(19) United States
(12) Patent Application Publication
(10) Pub. No.: US 2012/0155198 A1
(43) Pub. Date: Jun. 21, 2012

(54) SEMICONDUCTOR STORAGE DEVICE

(75) Inventor: Osamu HIRABAYASHI, Suginami-ku (JP)

(73) Assignee: KABUSHIKI KAISHA TOSHIBA, Tokyo (JP)

(21) Appl. No.: 13/232,819

(22) Filed: Sep. 14, 2011

(30) Foreign Application Priority Data
Dec. 21, 2010 (JP) 2010-284142

(51) Int. Cl. G11C 7/12; G11C 7/00

(52) U.S. Cl. 365/189.16

(57) ABSTRACT

According to one embodiment, a read bit line is driven based on data read out from a memory cell. A read port drives the read bit line based on data stored in a storage node. A read word line performs row selection via the read port at a time of reading from the memory cell. A coupling driver assists a write operation to the memory cell by controlling a potential of the storage node via the read port.

### CROSS-REFERENCE TO RELATED APPLICATIONS

This application is based upon and claims the benefit of priority from the prior Japanese Patent Application No. 2010-284142, filed on Dec. 21, 2010; the entire contents of which are incorporated herein by reference.

### FIELD Embodiments described herein relate generally to a semiconductor storage device.

### BACKGROUND

In LSIs used in portable devices, low power consumption is required to extend battery life. Reduction of a power supply voltage is effective for low power consumption, however, because of increase in characteristic variation of elements due to the recent progress in scaling, an operation margin of an SRAM used in an LSI decreases, so that it becomes difficult to reduce an operating voltage of an SRAM. Therefore, the operating voltage of an SRAM is limited, so that the power supply voltage of the whole LSI cannot be reduced.

In a conventional six-transistor SRAM cell, when a word line is selected, the potential of a storage node of a flip-flop is pulled to the potential of a bit line and thus data stored in the flip-flop becomes unstable. Therefore, when the power supply voltage decreases, a margin for storing data in the flip-flop cannot be ensured, which results in data corruption. For solving such read disturb, there is a method of separating a read port by composing the SRAM cell of eight transistors. In this eight-transistor SRAM cell, even when a word line is selected at the time of reading, a storage node of a flipflop remains isolated from a bit line, so that the potential of the storage node of the flip-flop is not pulled to the potential of the bit line, enabling to prevent read disturb.

On the other hand, in the eight-transistor SRAM cell, at the time of a write operation, when the word line is selected, the storage node of the flipflop is connected to the bit line. Therefore, when the power supply voltage is reduced, a margin for writing data in the flip-flop cannot be ensured, so that write failure occurs in some cases.

### BRIEF DESCRIPTION OF THE DRAWINGS

FIG. 1 is a circuit diagram illustrating a schematic configuration of a semiconductor storage device according to a first embodiment;

FIG. 2 is a timing chart illustrating a voltage waveform of each unit at the time of a write operation of the semiconductor storage device in FIG. 1;

FIG. 3 is a circuit diagram illustrating a schematic configuration of a semiconductor storage device according to a second embodiment; and

FIG. 4 is a circuit diagram illustrating a schematic configuration of a semiconductor storage device according to a third embodiment.

### DETAILED DESCRIPTION

In general, according to a semiconductor storage device of embodiments, a memory cell, a pair of bit lines, a write word line, a read bit line, a read port, a read word line, and a coupling driver are included. In the memory cell, a pair of storage nodes that complementarily stores therein data is provided. The pair of bit lines is complementarily driven based on data to be written in the memory cell. The write word line performs row selection at a time of writing to the memory cell. The read bit line is driven based on data read out from the memory cell. The read port drives the read bit line based on data stored in the storage node. The read word line performs row selection via the read port at a time of reading from the memory cell. The coupling driver assists a write operation to the memory cell by controlling a potential of the storage node via the read port.

A semiconductor storage device according to the embodiments will be explained below with reference to the drawings. The present invention is not limited to these embodiments.

### First Embodiment

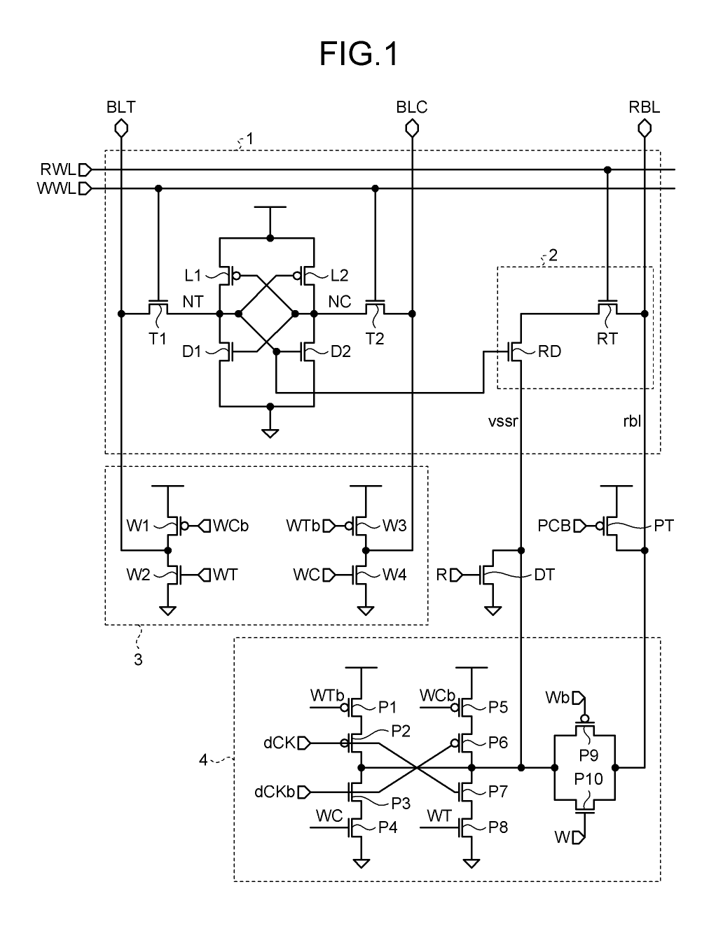

FIG. 1 is a circuit diagram illustrating a schematic configuration of a semiconductor storage device according to the first embodiment.

In FIG. 1, this semiconductor storage device includes a memory cell 1, a read port 2, a write driver 3, a coupling driver 4, a ground transistor DT, and a precharge transistor PT. The memory cell 1 can complementarily store therein data, and, for example, an eight-transistor SRAM cell can be used for the memory cell 1. In the memory cell 1, the read port 2 is provided which separates a read path of data from the memory cell 1 from a write path of data to the memory cell 1.

Specifically, the memory cell 1 includes a pair of drive transistors D1 and D2, a pair of load transistors L1 and L2, a pair of transfer transistors T1 and T2, a read-only transfer transistor RT, and a read-only drive transistor RD. The threshold voltages of the read-only transfer transistor RT and the read-only drive transistor RD are preferably lower than the threshold voltages of the drive transistors D1 and D2 and the transfer transistors T1 and T2.

P-channel field-effect transistors can be used as the load transistors L1 and L2, and N-channel field-effect transistors can be used as the drive transistors D1 and D2, the transfer transistors T1 and T2, the read-only transfer transistor RT, and the read-only drive transistor RD.

Moreover, in this memory cell 1, a write word line WWL for writing, a read word line RWL for reading, a pair of bit lines BLT and BLC, and a read bit line RBL for reading are provided. The write word line WWL and the read word line RWL can be arranged parallel to each other. Moreover, the bit lines BLT and BLC and the read bit line RBL can be arranged orthogonal to the write word line WWL and the read word line RWL.

The drive transistor D1 and the load transistor L1 are connected in series with each other to form a CMOS inverter and a storage node NT is provided at the connection point of the drive transistor D1 and the load transistor L1. The drive transistor D2 and the load transistor L2 are connected in series with each other to form a CMOS inverter and a storage node NC is provided at the connection point of the drive transistor D2 and the load transistor L2. The outputs and the inputs of a pair of the CMOS inverters are cross-coupled to each other to form a flip-flop.

The gate of the drive transistor D2, the gate of the load transistor L2, the drain of the drive transistor D1, and the drain of the load transistor L1 are connected to the drain of the transfer transistor T1, the bit line BLT is connected to the source of the transfer transistor T1, and the write word line WWL is connected to the gate of the transfer transistor T1.

The drain of the drive transistor D2, the drain of the load transistor L2, the gate of the drive transistor D1, and the gate of the load transistor L1 are connected to the drain of the transfer transistor T2, the bit line BLC is connected to the source of the transfer transistor T2, and the write word line WWL is connected to the gate of the transfer transistor T2.

The gate of the drive transistor D2, the gate of the load transistor L2, the drain of the drive transistor D1, and the drain of the load transistor L1 are connected to the gate of the read-only drive transistor RD.

The drain of the read-only drive transistor RD is connected to the drain of the read-only transfer transistor RT, the read bit line RBL is connected to the source of the read-only transfer transistor RT, and the read word line RWL is connected to the gate of the read-only transfer transistor RT.

The write driver 3 can complementarily drive the bit lines BLT and BLC at the time of a write operation of data to the memory cell 1. In other words, the write driver 3 can set the bit line BLC to a low level when the bit line BLT is set to a high level and set the bit line BLC to a high level when the bit line BLT is set to a low level.

Specifically, the write driver 3 includes write transistors W1 to W4. P-channel field-effect transistors can be used as the write transistors W1 and W3 and N-channel field-effect transistors can be used as the write transistors W2 and W4.

The write transistors W1 and W2 are connected in series with each other and the connection point thereof is connected to the bit line BLT. The write transistors W3 and W4 are connected in series with each other and the connection point thereof is connected to the bit line BLC. Moreover, a write control inverted signal WCb is input to the gate of the write transistor W1, a write control signal WT is input to the gate of the write transistor W2, a write control inverted signal WTb is input to the gate of the write transistor W3, and a write control signal WC is input to the gate of the write transistor W4. In a read operation, the write control signals WT and WC are set to a low level. In a write operation, when the write control signal WT is a low level, the write control signal WC is set to a high level, and when the write control signal WT is a high level, the write control signal WC is set to a low level. The write control inverted signal WTb is a signal obtained by inverting the write control signal WT and the write control inverted signal WCb is a signal obtained by inverting the write control signal WC.

The coupling driver 4 can assist a write operation to the memory cell 1 by controlling the potential of the storage node NT via the read port 2. The coupling driver 4 can control the potential of the storage node NT based on the capacitive coupling between the read port 2 and the storage node NT. Moreover, in order to assist a write operation to the memory cell 1, the coupling driver 4 can control the potential of the storage node NT to match the direction of the potential according to write data at the time of a write operation to the memory cell 1. The coupling driver 4 can be provided for each column. When there is a column select circuit, the coupling driver 4 can be provided for each data input/output circuit.

Specifically, the coupling driver 4 includes coupling control transistors P1 to P10. P-channel field-effect transistors can be used as the coupling control transistors P1, P2, P5, P6, and P9, and N-channel field-effect transistors can be used as the coupling control transistors P3, P4, P7, P8, and P10.

The coupling control transistors P1 to P4 are connected in series with each other and the connection point of the coupling control transistors P2 and P3 is connected to the source of the read-only drive transistor RD. The coupling control transistors P5 to P8 are connected in series with each other and the connection point of the coupling control transistors P6 and P7 is connected to the source of the read-only drive transistor RD. The coupling control transistors P9 and P10 are connected in parallel with each other and the drains of the coupling control transistors P9 and P10 are connected to the read bit line RBL and the sources of the coupling control transistors P9 and P10 are connected to the source of the read-only drive transistor RD.

Moreover, the write control inverted signal WTb is input to the gate of the coupling control transistor P1 and the write control inverted signal WCb is input to the gate of the coupling control transistor P5. The write control signal WC is input to the gate of the coupling control transistor P4 and the write control signal WT is input to the gate of the coupling control transistor P8. A clock signal dCK is input to the gates of the coupling control transistors P2 and P7 and a clock inverted signal dCKb is input to the gates of the coupling control transistors P3 and P6. The clock inverted signal dCKb is a signal obtained by inverting the clock signal dCK. A write enable inverted signal Wb is input to the gate of the coupling control transistor P9 and a write enable signal W is input to the gate of the coupling control transistor P10. The write enable inverted signal Wb is a signal obtained by inverting the write enable signal W.

The source of the read-only drive transistor RD is grounded via the ground transistor DT. A read enable signal R is input to the gate of the ground transistor DT. An N-channel field-effect transistor can be used as the ground transistor DT.

Moreover, the read bit line RBL is connected to the power supply potential via the precharge transistor PT. A precharge signal PCB is input to the gate of the precharge transistor PT. A P-channel field-effect transistor can be used as the precharge transistor PT.

In a read operation, the read enable signal R rises and thus the ground transistor DT is turned on, so that the source of the read-only drive transistor RD is grounded. Moreover, before the potential of the read word line RWL rises, the precharge signal PCB is set to a low level and thus the precharge transistor PT is turned on, so that the read bit line RBL is precharged to a high level.

When the read bit line RBL is precharged to a high level, the precharge signal PCB rises and thus the precharge transistor PT is turned off, so that the read word line RBL is separated from the power supply potential.

When the potential of the read word line RWL rises, the read-only transfer transistor RT is turned on. Therefore, the read bit line RBL is driven via the read-only drive transistor RD according to data stored in the storage node NT, so that the data stored in the storage node NT is read out via the read bit line RBL.

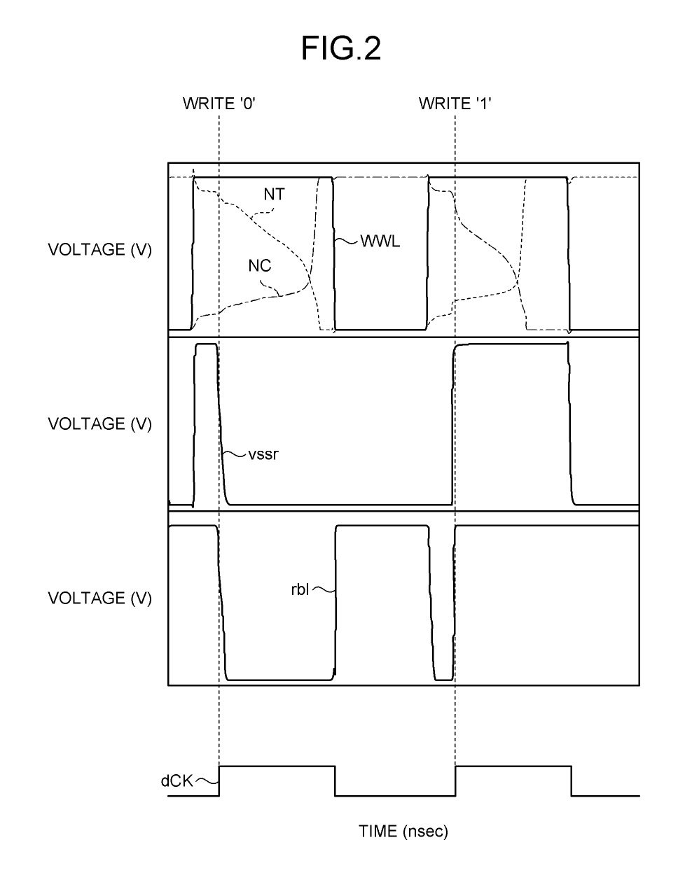

FIG. 2 is a timing chart illustrating a voltage waveform of each unit at the time of a write operation of the semiconductor storage device in FIG. 1. “vssr” indicates the source potential of the read-only drive transistor RD and “rbl” indicates the potential of the read bit line RBL.

In FIG. 2, in a write operation of the semiconductor storage device in FIG. 1, when a logical value ‘0’ is written in the storage node NT, the write control signal WT is set to a high level and the write control signal WC is set to a low level. Therefore, the write transistors W1 and W4 are turned off and the write transistors W2 and W3 are turned on, so that the bit line BLT is set to a low level and the bit line BLC is set to a high level.

Then, after the potentials of the bit lines BLT and BLC are determined according to the write data, when the potential of the write word line WWL rises, the transfer transistors T1 and T2 are turned on. Therefore, the potentials of the bit lines BLT and BLC are applied to the storage nodes NT and NC via the transfer transistors T1 and T2, respectively, whereby the potential of the storage node NT is made to fall to a low level and the potential of the storage node NC is made to rise to a high level.

Moreover, when the write control signal WT is set to a high level and the write control signal WC is set to a low level, the coupling control transistors P1 and P8 are turned on and the coupling control transistors P4 and P5 are turned off. Furthermore, before the clock signal dCK rises, the coupling control transistors P2 and P3 are on and the coupling control transistors P6 and P7 are off.

Therefore, the source of the read-only drive transistor RD is connected to the power supply potential via the coupling control transistors P1 and P2, so that the source of the read-only drive transistor RD is set to a high level.

Then, when the clock signal dCK rises after the potential of the write word line WWL rises, the coupling control transistors P2 and P3 are turned off and the coupling control transistors P6 and P7 are turned on.

Therefore, the source of the read-only drive transistor RD is connected to the ground potential via the coupling control transistors P7 and P8, so that the source of the read-only drive transistor RD is set to a low level.

Moreover, in a write operation, the write enable signal W becomes a high level, so that the coupling control transistors P9 and P10 are turned on and thus the source of the read-only drive transistor RD is connected to the read bit line RBL. Furthermore, when the potential of the read word line RWL is set to a high level, the read-only transfer transistor RT is turned on. Therefore, the source of the read-only drive transistor RD is connected to the drain of the read-only drive transistor RD via the read bit line RBL and the source and the drain of the read-only drive transistor RD are set to the same potential, so that the drain of the read-only drive transistor RD is set to a low level.

When the source and the drain of the read-only drive transistor RD are set to a low level, the source and the drain of the read-only drive transistor RD are capacitively coupled to the gate of the read-only drive transistor RD, so that the potential of the storage node NT is made to fall to a low level.

Therefore, when the logical value ‘0’ is written in the storage node NT, the potential of the storage node NT can be made to fall to a low level via the source and the drain of the read-only drive transistor RD while causing the potential of the storage node NT to fall to a low level via the bit line BLT.

On the other hand, when a logical value ‘1’ is written in the storage node NT, the write control signal WT is set to a low level and the write control signal WC is set to a high level. Therefore, the write transistors W1 and W4 are turned on and the write transistors W2 and W3 are turned off, so that the bit line BLT is set to a high level and the bit line BLC is set to a low level.

Then, after the potentials of the bit lines BLT and BLC are determined according to the write data, when the potential of the write word line WWL rises, the transfer transistors T1 and T2 are turned on. Therefore, the potentials of the bit lines BLT and BLC are applied to the storage nodes NT and NC via the transfer transistors T1 and T2, respectively, whereby the potential of the storage node NT is made to rise to a high level and the potential of the storage node NC is made to fall to a low level.

Moreover, when the write control signal WT is set to a low level and the write control signal WC is set to a high level, the coupling control transistors P1 and P8 are turned off and the coupling control transistors P4 and P5 are turned on. Furthermore, before the clock signal dCK rises, the coupling control transistors P2 and P3 are on and the coupling control transistors P6 and P7 are off.

Therefore, the source of the read-only drive transistor RD is connected to the ground potential via the coupling control transistors P3 and P4, so that the source of the read-only drive transistor RD is set to a low level.

Then, when the clock signal dCK rises after the potential of the write word line WWL rises, the coupling control transistors P2 and P3 are turned off and the coupling control transistors P6 and P7 are turned on.

Therefore, the source of the read-only drive transistor RD is connected to the power supply potential via the coupling control transistors P5 and P6, so that the source of the read-only drive transistor RD is set to a high level.

Moreover, in a write operation, the write enable signal W becomes a high level, so that the coupling control transistors P9 and P10 are turned on and thus the source of the read-only drive transistor RD is connected to the read bit line RBL. Furthermore, when the potential of the read word line RWL is set to a high level, the read-only transfer transistor RT is turned on. Therefore, the source of the read-only drive transistor RD is connected to the drain of the read-only drive transistor RD via the read bit line RBL and the source and the drain of the read-only drive transistor RD are set to the same potential, so that the drain of the read-only drive transistor RD is set to a high level.

When the source and the drain of the read-only drive transistor RD are set to a high level, the source and the drain of the read-only drive transistor RD are capacitively coupled to the gate of the read-only drive transistor RD, so that the potential of the storage node NT is made to rise to a high level.

Therefore, when the logical value ‘1’ is written in the storage node NT, the potential of the storage node NT can be made to rise to a high level via the source and the drain of the read-only drive transistor RD while causing the potential of the storage node NT to rise to a high level via the bit line BLT.

Consequently, the coupling driver 4 can change the potential of the storage node NT to match the direction of the potential according to write data at the time of a write operation to the memory cell 1, enabling to assist a write operation to the memory cell 1.

Therefore, when data stored in the storage nodes NT and NC cannot be inverted only by driving the storage nodes NT and NC via the bit lines BLT and BLC due to reduction in the power supply voltage, the data stored in the storage nodes NT and NC can be inverted, so that write failure can be reduced.

In the memory cell 1 on a nonselected row on a selected column, the write word line WWL is set to a low level and the storage nodes NT and NC are not driven via the bit lines BLT and BLC, so that erroneous writing can be prevented.

Moreover, in the memory cell 1 on a nonselected column on a selected row, although the storage nodes NT and NC are driven via the bit lines BLT and BLC, assist by the coupling driver 4 is not performed, so that erroneous writing can be prevented.

Furthermore, the threshold voltages of the read-only transfer transistor RT and the read-only drive transistor RD are set to be lower than the threshold voltages of the drive transistors D1 and D2 and the transfer transistors T1 and T2, so that switching speed of the read-only transfer transistor RT and the read-only drive transistor RD can be increased, enabling to improve the coupling efficiency by the coupling driver 4.

In the embodiment in FIG. 1, explanation is given for the method in which the coupling driver 4 controls the potential of the storage node NT via the read port 2 for assisting a write operation to the memory cell 1, however, the coupling driver 4 can control the potential of the storage node NC via the read port.

Moreover, in the embodiment in FIG. 1, the eight-transistor SRAM cell in which the read port 2 is connected to the storage node NT is explained as an example, however, it is applicable to apply to a 10-transistor SRAM cell in which the read port is connected separately to each of the storage nodes NT and NC.

Furthermore, in the embodiment in FIG. 2, explanation is given for the method in which the coupling driver 4 controls the potential of the storage node NT to match the direction of the potential according to write data after once controlling the potential of the storage node NT to be different from the direction of the potential according to the write data at the time of a write operation to the memory cell 1, however, it is applicable to control the potential of the storage node NT to match the direction of the potential according to write data without once controlling the potential of the storage node NT to be different from the direction of the potential according to the write data.

### Second Embodiment

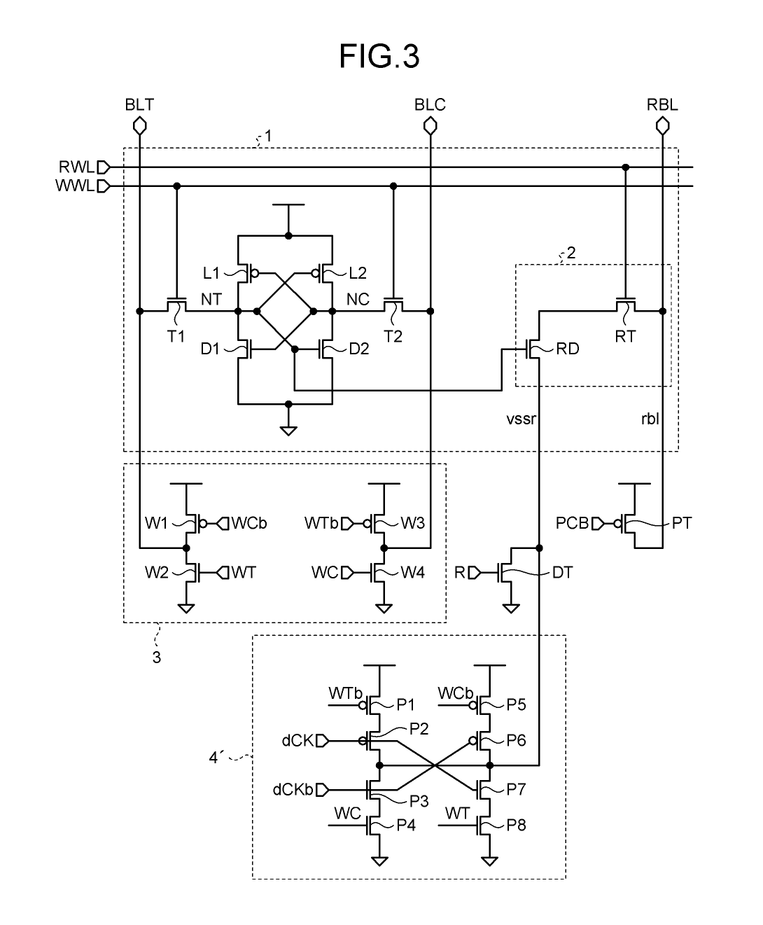

FIG. 3 is a circuit diagram illustrating a schematic configuration of a semiconductor storage device according to the second embodiment.

In FIG. 3, this semiconductor storage device includes a coupling driver 4′ instead of the coupling driver 4 of the semiconductor storage device in FIG. 1. In the coupling driver 4′, the coupling control transistors P9 and P10 in FIG. 1 are omitted. Therefore, whereas, in the coupling driver 4 in FIG. 1, assistance for a write operation is performed based on the capacitive coupling between both the source and the drain of the read-only drive transistor RD and the gate of the read-only drive transistor RD, in the coupling driver 4′ in FIG. 3, assistance for a write operation is performed based on the capacitive coupling between the source of the read-only drive transistor RD and the gate of the read-only drive transistor RD.

Consequently, assistance for writing to the memory cell 1 can be performed while enabling to reduce the number of elements in the coupling driver 4′ compared with the coupling driver 4, so that when the read port 2 that prevents read disturb is provided to the memory cell 1, write failure can be reduced.

### Third Embodiment

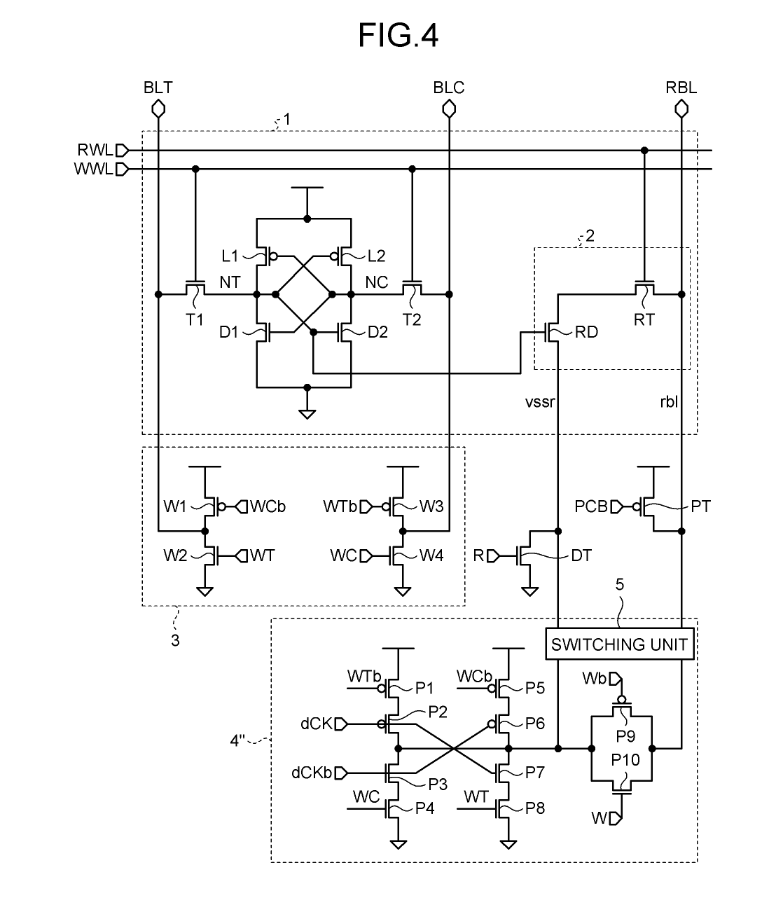

FIG. 4 is a circuit diagram illustrating a schematic configuration of a semiconductor storage device according to the third embodiment.

In FIG. 4, this semiconductor storage device includes a coupling driver 4″ instead of the coupling driver 4 of the semiconductor storage device in FIG. 1. In the coupling driver 4″, a switching unit 5 is added to the coupling driver 4 in FIG. 1. The switching unit 5 can disable assistance for a write operation by the coupling driver 4″. As this switching unit 5, for example, a fuse element that separates the coupling driver 4″ from the memory cell 1 can be used. Setting of this switching unit 5 can be performed in the stage of a writing test before product shipment.

Consequently, it is possible to control such that assistance for a write operation by the coupling driver 4″ is performed only on a column having the memory cell 1 causing write failure and assistance for a write operation by the coupling driver 4″ is not performed on a column having no memory cell 1 causing write failure, so that increase in power consumption by the coupling driver 4″ can be suppressed.

In the example in FIG. 4, explanation is given for the method of providing the switching unit 5 for disabling assistance for a write operation by the coupling driver 4″, however, for example, the write control signals WT and WC can be fixed to a low level.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a memory cell, the memory cell comprising a pair of storage nodes configured to complementarily store data;
a pair of bit lines configured to be complementarily driven based on data written in the memory cell;
a write word line configured to perform row selection at a time of writing to the memory cell;
a read bit line configured to be driven based on data read out from the memory cell;
a read port in the memory cell, the read port configured to drive the read bit line based on data stored in the storage node;
a read word line configured to perform row selection via the read port at a time of reading from the memory cell; and
a coupling driver configured to assist a write operation to the memory cell by controlling a potential of the storage node via the read port.

2. The semiconductor storage device according to claim 1, wherein the coupling driver is configured to control the potential of the storage node based on capacitive coupling between the read port and the storage node.

3. The semiconductor storage device according to claim 1, wherein the coupling driver is configured to control the potential of the storage node to match a direction of a potential according to write data at a time of a write operation to the memory cell.

4. The semiconductor storage device according to claim 1, wherein the coupling driver is configured to control the potential of the storage node to match a direction of a potential according to write data after once controlling the potential of the storage node to become different from the direction of the potential according to the write data at a time of a write operation to the memory cell.

5. The semiconductor storage device according to claim 1, further comprising a write driver configured to complementarily drive the pair of bit lines at a time of a write operation of data to the memory cell.

6. The semiconductor storage device according to claim 5, wherein the memory cell includes:
a first drive transistor;
a second drive transistor;
a first load transistor connected in series with the first drive transistor;
a second load transistor connected in series with the second drive transistor;
a first transfer transistor comprising a drain connected to a gate of the second drive transistor, a gate of the second load transistor, a drain of the first drive transistor, and a drain of the first load transistor, a source connected to one of the pair of bit lines, and a gate connected to the write word line;
a second transfer transistor comprising a drain connected to a drain of the second drive transistor, a drain of the second load transistor, a gate of the first drive transistor, and a gate of the first load transistor, a source connected to another of the pair of bit lines, and a gate is connected to the write word line;
a read-only drive transistor comprising a gate connected to a gate of the second drive transistor, a gate of the second load transistor, a drain of the first drive transistor, and a drain of the first load transistor; and
a read-only transfer transistor comprising a drain connected to a drain of the read-only drive transistor, a source connected to the read bit line, and a gate connected to the read word line.

7. The semiconductor storage device according to claim 6, wherein the read-only drive transistor and the read-only transfer transistor are in the read port.

8. The semiconductor storage device according to claim 6, wherein the coupling driver is configured to control the potential of the storage node based on capacitive coupling between at least any one of a source and a drain of the read-only drive transistor and a gate of the read-only drive transistor.

9. The semiconductor storage device according to claim 6, wherein a threshold voltage of the read-only drive transistor and the read-only transfer transistor is lower than a threshold voltage of the first drive transistor, the second drive transistor, the first transfer transistor, and the second transfer transistor.

10. The semiconductor storage device according to claim 6, wherein the coupling driver includes:
a first coupling control transistor comprising a gate receiving a first write control inverted signal input;
a second coupling control transistor connected in series with the first coupling control transistor and which comprises a gate receiving a clock signal input;
a third coupling control transistor connected in series with the second coupling control transistor and which comprises a gate receiving a clock inverted signal input;
a fourth coupling control transistor connected in series with the third coupling control transistor and which comprises a gate receiving a second write control signal input;
a fifth coupling control transistor comprising a gate receiving a second write control inverted signal input;
a sixth coupling control transistor connected in series with the fifth coupling control transistor and comprising a gate receiving the clock inverted signal;
a seventh coupling control transistor connected in series with the sixth coupling control transistor and comprising a gate receiving as input the clock signal; and
an eighth coupling control transistor connected in series with the seventh coupling control transistor and comprising a gate receiving a first write control signal input; and
a connection point of the second coupling control transistor and the third coupling control transistor and a connection point of the sixth coupling control transistor and the seventh coupling control transistor connected to a source of the read-only drive transistor.

11. The semiconductor storage device according to claim 10, wherein the device is configured such that:
in a read operation, the first write control signal and the second write control signal are set to a low level; and
in a write operation, when the first write control signal is a low level, the second write control signal is set to a high level and, when the first write control signal is a high level, the second write control signal is set to a low level.

12. The semiconductor storage device according to claim 11, wherein the coupling driver includes:
a ninth coupling control transistor comprising a gate receiving a write enable inverted signal as input; and
a tenth coupling control transistor connected in parallel with the ninth coupling control transistor and comprising a gate receiving a write enable signal as input,
and wherein a first connection point of the ninth coupling control transistor and the tenth coupling control transistor connected to a source of the read-only drive transistor, and
a second connection point of the ninth coupling control transistor and the tenth coupling control transistor connected to the read bit line.

13. The semiconductor storage device according to claim 12, wherein the device is configured such that the write enable signal is set to a high level in a read operation.

14. The semiconductor storage device according to claim 13, wherein the write driver includes:
a first write transistor comprising a gate receiving the second write control inverted signal as input,
a second write transistor connected in series with the first write transistor and comprising a gate receiving the first write control signal as input,
a third write transistor comprising a gate receiving the second write control inverted signal as input, and
a fourth write transistor connected in series with the third write transistor and comprising a gate receiving the second write control signal as input,
a connection point of the first write transistor and the second write transistor connected to a first bit line of the pair of bit lines, and
a connection point of the third write transistor and the fourth write transistor connected to a second bit line of the pair of bit lines.

15. The semiconductor storage device according to claim 14, further comprising a precharge transistor in which a drain is connected to the read bit line and a precharge signal is input to a gate.

16. The semiconductor storage device according to claim 15, wherein the device is configured such that before a potential of the read word line rises, the read bit line is precharged to a high level by setting the precharge signal to a low level and turning on the precharge transistor.

17. The semiconductor storage device according to claim 16, further comprising a ground transistor in which a drain is connected to the source of the read-only drive transistor and a read enable signal is input to a gate.

18. The semiconductor storage device according to claim 17, wherein the device is configured such that in the read operation, the source of the read-only drive transistor is grounded by causing the read enable signal to rise and turning on the ground transistor.

19. The semiconductor storage device according to claim 1, wherein the coupling driver includes a switching unit configured to disable assistance for a write operation.

20. The semiconductor storage device according to claim 19, wherein the switching unit is configured to disable assistance for the write operation for a column having no memory cell causing write failure and enables assistance for the write operation for a column having a memory cell causing write failure.
